(19) United States
(12) Patent Application Publication
(10) Pub. No.: US 2009/0079064 A1
(43) Pub. Date: Mar. 26, 2009

(54) METHODS OF FORMING A THIN TIM CORELESS HIGH DENSITY BUMP-LESS PACKAGE AND STRUCTURES FORMED THEREBY

(76) Inventors: Jiamiao Tang, Shanghai (CN); Daoqiang Lu, Chandler, AZ (US); Rougang Zhao, Shanghai (CN)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/861,183

(22) Filed: Sep. 25, 2007

(51) Int. Cl. H01L 23/34; H01L 21/00

(52) U.S. Cl. 257/723; 438/113; 257/E23.08

(57) ABSTRACT

Methods of forming microelectronic device structures are described. Those methods may include placing a plurality of support rings onto a tacky layer of a support carrier, wherein the support rings are disposed within a cavity of the support carrier; placing a plurality of thin die onto a pedestal of the support carrier, wherein a top surface of the thin die is substantially flush with at top surface of the support ring; and then building up layers on the top surface of the die.

### BACKGROUND OF THE INVENTION

Thin microelectronic die can offer many advantages when used in packaging applications. For example, thermal and electrical performance may be enhanced when using such a thin die in microelectronic structures and/or microelectronic packaging structures.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1m represent structures according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods of forming microelectronic structures are described. Those methods may include placing a plurality of support rings onto a tacky layer of a support carrier, wherein the support rings are disposed within a cavity of the support carrier; placing a plurality of thin die onto a pedestal of the support carrier, wherein a top surface of the thin die is substantially flush with at top surface of the support ring; and then building up layers on the top surface of the die. Methods of the present invention enable the utilization of a thin die with a thin thermal interface material (TIM) in a high density coreless bumpless microelectronic package, for example. Such an implementation significantly improves thermal and/or electrical performance of microelectronic structures utilizing the methods and structures of the present invention.

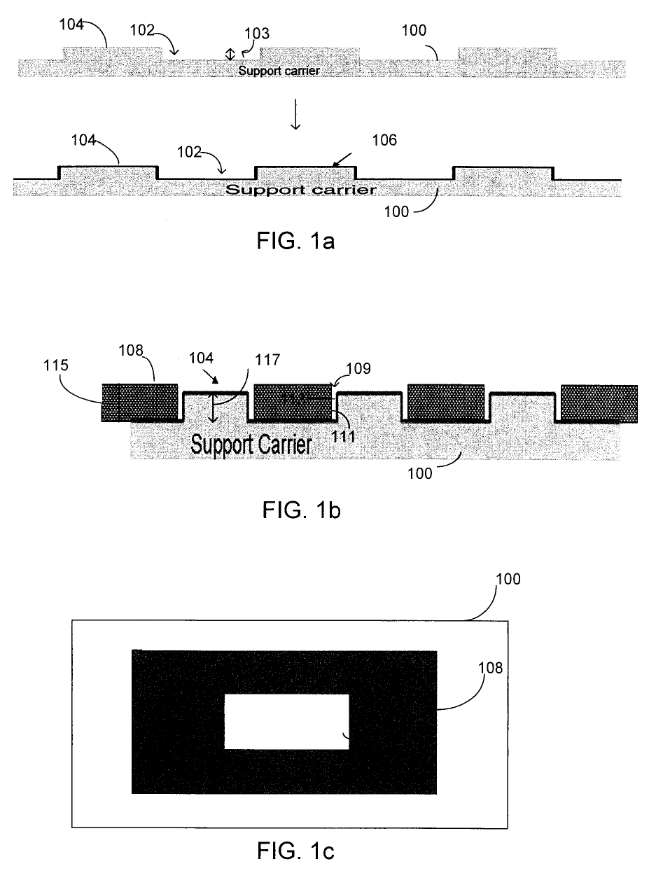

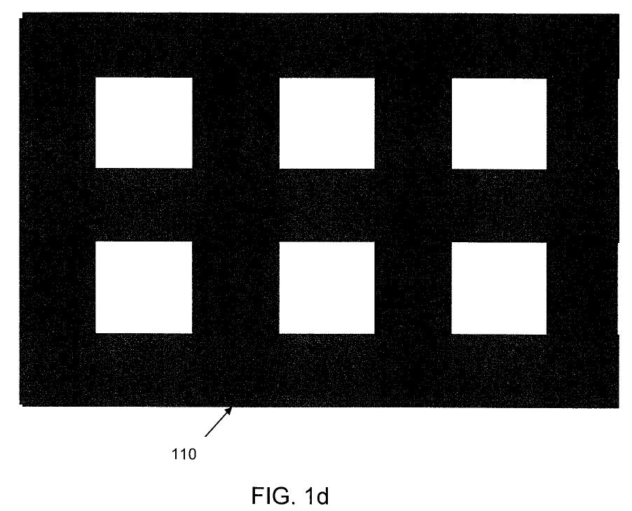

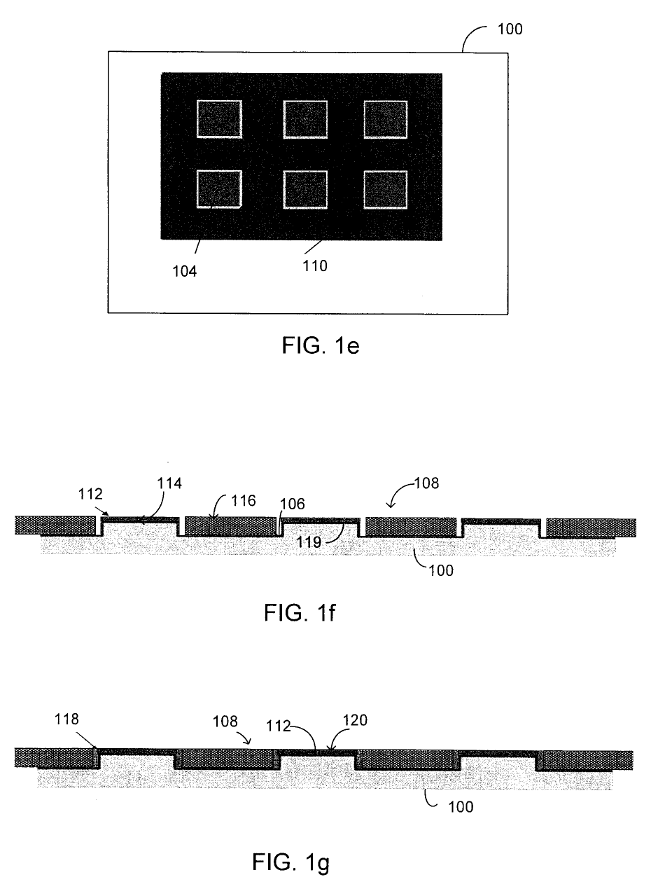

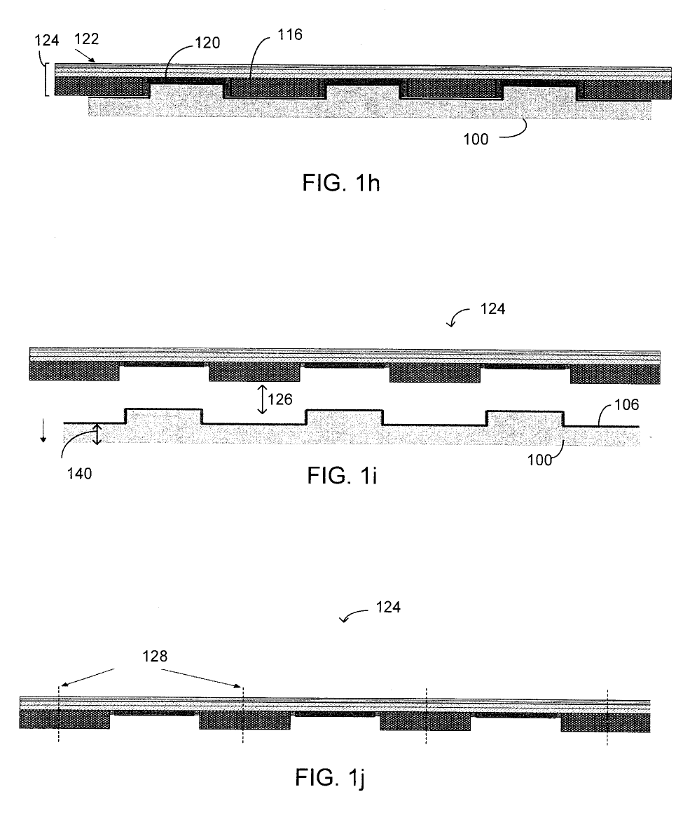

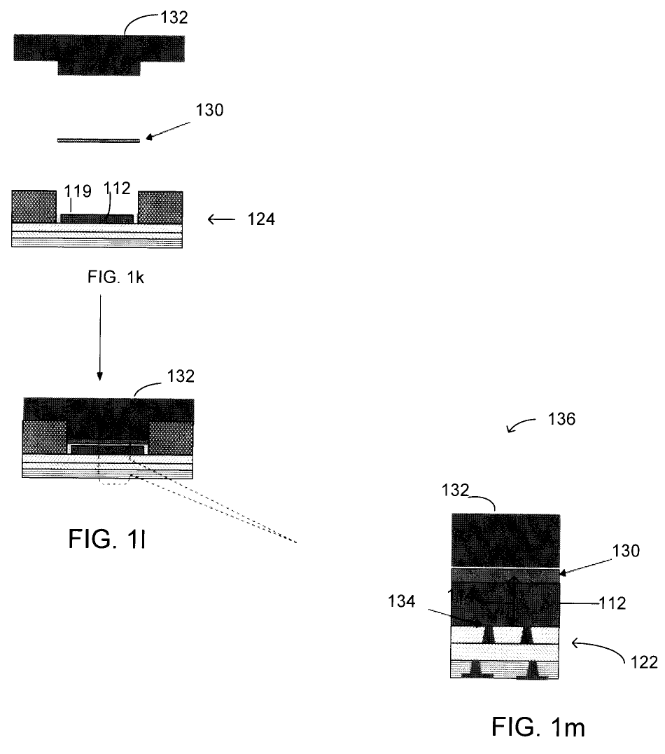

FIGS. 1a-1m illustrate embodiments of methods of forming microelectronic structures, such as methods for forming portions a bumpless, coreless microelectronic package, for example. FIG. 1a illustrates a cross-section of a substrate carrier 100. The substrate carrier 100 may provide a support structure for the placement of die, and may further comprise a pedestal 104 and cavity 102. The cavity may comprise a depth 103, wherein the magnitude of the depth 103 may depend upon the particular application.

A releasable layer 106 may be formed on the substrate carrier 100 to substantially cover the pedestal 104 and the cavity 102. In one embodiment, the releasable layer 106 may comprise a layer of silicone which may be subsequently cured. In other embodiments, the releasable layer 106 may comprise any material that may be tacky after curing, and may provide substantial adhesion for the subsequent placement of die onto the support carrier 100, but yet may not be so strongly adhesive as to prevent the release of die from the support carrier 100 during subsequent processing steps.

At least one support ring 108 may be placed onto the release layer 108, wherein individual support rings 108 may be placed within individual cavities 102 (FIG. 1b). In one embodiment, the individual ones of the at least one support ring 108 may be placed utilizing a pick and place technique, as is known in the art. In one embodiment, the at least one support rings 108 may comprise at least one of FR4 (flame retardant 4), copper, SS (stainless steel), aluminum, silicon, and ceramic materials. In one embodiment, a height 115 of the at least one support ring 108 may be higher than a height 117 of the pedestal 104. In one embodiment, the difference in the heights 115, 117 of the support ring and the pedestal 104 may be on the order of a height (i.e. thickness) of a die that may be subsequently placed onto the pedestal 104. There may be a gap 109 that may exist between a sidewall 111 of the at least one support ring 108 and a sidewall 113 of the pedestal 104 of the support carrier 100.

FIG. 1c depicts a top view of the support ring 108 disposed on the support carrier 100, wherein the cavity 102 is surrounded by the support ring 108. In another embodiment, the at least one support ring 108 may be pre-fashioned into a panel of support rings 110 (FIG. 1d), so that the panel of support rings 110 may be placed into a plurality of cavities 102 of the support carrier 100 (FIG. 1e). In one embodiment, the heights 115 of the panel of support rings 110 may be higher than the heights 117 of the plurality of pedestals 104 they surround.

In one embodiment, at least one die 112 may be placed onto at least one pedestal 104 (FIG. 1f), such that a transistor side of the die is facing upwards, and a backside 119 of the die is disposed on the release layer 106. In one embodiment, the at least one die may be placed onto the at least one pedestal 104 by utilizing a pick and place process. The releasable layer 106 may hold the at least one die 112 substantially flat and in place on the at least one pedestal 104 of the substrate carrier 100.

In one embodiment, a thickness 114 of the at least one die 112 may be substantially the same as the difference in the heights 115, 117 of the support ring 108 and the pedestal 104. In one embodiment, the thickness 114 of the at least one die 112 may comprise about 25 microns to about 500 microns. In one embodiment, the at least one die 112 may be substantially flush with a top surface 116 of the at least one support ring 108. In this manner, die warpage may be significantly decreased and/or eliminated, thus greatly improving reliability and yield during manufacturing of devices utilizing the various embodiments of the present invention.

In one embodiment, an encapsulant 118 may be dispensed within the gap 109, which may serve to encapsulate the at least one die 112 inside of the substrate carrier 100 (FIG. 1g). The encapsulant 118 may then be cured, and in some embodiments the encapsulent 118 may comprise a low viscosity polymer. The encapsulant 118 may substantially fill in the gap 109, and may further connect the at least one die 112 to the at least one support ring 108. In some cases, the encapsulent may comprise a material that is mechanically strong. Sufficient care should be taken to ensure that substantially no encapsulant 118 may be dispensed onto a top surface 120 of the at least one die 112 because the encapsaulant might contaminate the conductive pads on the die top side and interfere with the electrical connection between the die and build up layers.

In some embodiments, the encapsulant 118 may provide mechanical rigidity and strength for the die 112 disposed on the substrate carrier 100, thus decreasing die warpage problems. Because the at least one support ring 108 is placed on the substrate carrier before the build up layers, the thickness of the die can be tailored to be substantially the same as the difference in height between the pedestal and the at least one support ring, so this allows for the placement of a very thin TIM (during subsequent assembly processing) in a substantially flat manner, and also provides for mechanical rigidity which allows for avoidance of die warpage.

Various substrate build up layers 122 may be added to the top surface 120 of the at least one die 112 and the top surface 116 of the support ring 108 (FIG. 1h), wherein the substrate build up layers 122 may comprise a portion of a package, for example. The build up layers 122 may comprise materials such as dielectric layers, and copper layers, but the particular composition of the build up layers 122 will depend upon the particular application.

In one embodiment, the substrate build up layers 122, the at least one die 112, the encapsulant 118 and the at least one support ring 108 may comprise a portion of a package structure 124. In one embodiment, the package structure 124 may comprise a portion of a high density, coreless, bump-less package structure 124, wherein the at least one die 112 may be electrically connected to the package substrate build up layers 122 without the use of bumps, such without the use of solder bumps, for example.

The support carrier 100 may be released 126 from the package structure 124 by pulling the support carrier 100 away from the package structure 124 (FIG. 1i). Due to the weaker adhesion between the release layer 106 and the at least one die 112, as compared with the adhesion of the at least one die 112 to the package structure 124, the substrate carrier 100 may be easily removed from the package structure 124. In one embodiment, the package structure 124 may be singulated 128 into separate portions containing a single die (FIG. 1j).

In one embodiment, a thermal interface material (TIM) 130 may be attached to the backside 119 of the at least one die 112 (FIG. 1k-FIG. 11). In one embodiment, the TIM 130 may comprise a thickness of about 10 microns to about 150 microns, and may comprise a solder perform in some embodiments. A heat removal structure 132, such as but not limited to a heat spreader, may be attached to the TIM 130. FIG. 1m depicts a portion of a portion of a high density, coreless, bump-less package structure 136, wherein the at least one die 112 may be electrically connected 134 to the build up layers 122 without the use of bumps, such without the use of solder bumps, for example.

The use of a thin microelectronic die 112 offers many advantages when used in packaging applications. For example, thermal performance may be enhanced when such a thin die 112 may be combined with a thin (TIM) 130. In some cases, the thickness 114 of such a thin die 112 may be much smaller than a thickness 140 of the substrate carrier 100 (FIG. 1i) that may be used to place the thin die 112 onto the package structure 124.

Thus, the benefits of the embodiments of the present invention include, but are not limited to, enablement of thin die, thin TIM high density coreless bumpless package fabrication, and significantly improving the thermal and electrical performance of such package structures. Because of the mechanical rigidity of the substrate carrier, the warpage of the build up layers may be substantially removed if not eliminated, and thus the finished final package will have very small amount of warpage.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices are well known in the art. Therefore, it is appreciated that the Figures provided herein illustrate only portions of an exemplary microelectronic structure that pertains to the practice of the present invention. Thus the present invention is not limited to the structures described herein.

What is claimed is:

1. A method comprising:
forming a release layer on a support carrier, wherein the support carrier comprises at least one pedestal;
placing a plurality of support rings onto the release layer;
placing a plurality of thin die onto the pedestal, wherein a top surface of the thin die is substantially flush with at top surface of the support ring;
filling a gap between a sidewall of the die and the support ring with an encapsulant;
building up layers on the top surface of the die.

2. The method of claim 1 further comprising releasing the support carrier from the release layer.

3. The method of claim 1 further comprising singulating the die into single packages.

4. The method of claim 1 further comprising attaching a thin TIM to a bottom surface of the die.

5. The method of claim 4 further comprising attaching a heat spreader to the thin TIM.

6. The method of claim 4 further comprising wherein at least one interconnect between the die and the build up layers comprises a bump-less die substrate interconnect.

7. A method comprising:
placing a plurality of support rings onto a release layer of a support carrier, wherein the support rings are disposed within a cavity of the support carrier;
placing a plurality of thin die onto a pedestal of the support carrier, wherein a top surface of the thin die is substantially flush with at top surface of the support ring;
building up layers on the top surface of the die.

8. The method of claim 7 further comprising filling a gap between a sidewall of the die and the support ring with an encapsulant.

9. The method of claim 7 further comprising wherein the die comprises a thickness between about 25 to about 500 microns.

10. The method of claim 7 further comprising attaching a TIM comprising to a bottom surface of the die.

11. The method of claim 10 further comprising wherein the TIM comprises a thickness between about 10 to about 150 microns.

12. The method of claim 7 further comprising wherein the die comprises a thickness between about 25 to about 500 microns.

13. A structure comprising:
a release layer disposed on a support carrier, wherein the support carrier comprises at least one pedestal and a cavity;
a plurality of support rings disposed in the cavity;
a plurality of thin die disposed on the pedestal, wherein a top surface of the thin die is substantially flush with at top surface of the support ring;
a plurality of building up layers disposed on the top surface of the die.

14. The structure of claim 13 further comprising a TIM disposed on a bottom surface of the die.

15. The structure of claim 13 further comprising an encapsulant disposed between a sidewall of the die and the support ring.

16. The structure of claim 13 further comprising wherein the die comprises a thickness between about 25 to about 500 microns.

17. The structure of claim 13 further comprising wherein the TIM comprises a thickness between about 10 to about 150 microns.

18. The structure of claim 13 further comprising wherein at least one interconnect between the die and the build up layers comprises a bump-less die substrate interconnect.

19. The structure of claim 17 further comprising a heat spreader disposed on the TIM.

20. The structure of claim 13 wherein the release layer comprises silicone.
